(19) United States
(12) Patent Application Publication
(10) Pub. No.: US 2008/0061837 A1
(43) Pub. Date: Mar. 13, 2008

(54) Low Supply Voltage, Large Output Swing, Source-Terminated Output Driver for High Speed AC-coupled Double-Termination Serial Links

(75) Inventors: Feng Xu, Shanghai (CN); Quan Yu, Shanghai (CN); Ming Qu, San Jose, CA (US)

Correspondence Address: THOMAS C. CHUANG, 255 BERRY ST., BOX 611, SAN FRANCISCO, CA, 94158, US

(73) Assignee: Parade Technologies, Ltd.

(21) Appl. No.: 11/467,528

(22) Filed: Aug. 25, 2006

(51) Int. Cl. H03K 19/086

(52) U.S. Cl. 326/127

(57) ABSTRACT

A current mode logic circuit includes a current mode logic driver circuit and a transistor biasing improvement circuit. The transistor biasing improvement circuit includes a first current source coupled to a first output node of the current mode logic driver circuit and a second current source coupled to a second output node of the current mode logic driver circuit. The first current source and the second current source raise a common mode voltage at the first output node and the second output node.

### BACKGROUND OF THE INVENTION

As data transfer requirements increase for both on-chip and inter-chip applications, transfer speed remains one of the most critical issues in modern integrated circuit design. Current mode logic (CML) is widely used in modern high speed data path designs for its superior speed performance. Referring to FIG. 1, a conventional approach to implement an AC-coupled double termination data transmission link is illustrated. A CML driver circuit 2 located internal to an integrated circuit chip 34 consists of a differential pair of transistors NMOS transistor M1 10, NMOS transistor M2 12, source termination resistors R1 4, R2 6, and a current source Iₛᵢₙₖ 38 that feeds the sources of the differential transistor pair. For any high speed data transmission over wireline, source termination resistors are used to reduce the reflections and thereby improve signal quality.

The CML driver circuit 2 utilizes NMOS transistors M1 10 and M2 12 as a differential logic pair. The gate electrode of NMOS transistor M1 10 is connected to an input line DIP 14, the source electrode is connected to constant-current source Iₛᵢₙₖ 38, and the drain electrode is connected to an output node 17 connected to chip pad DON 20 and source termination resistor R1 4. The gate electrode of NMOS transistor M2 12 is connected to input line DIN 16, the source electrode is connected to constant current source Iₛᵢₙₖ 38, and the drain electrode is connected to an output node 19 connected to chip pad DOP 18 and source termination resistor R2 6. A supply voltage V_{DD} 8 is coupled to R1 4 and R2 6.

In operation, for example, if an input signal and its reverse signal are inputted to CML driver circuit 2 from input lines DIP 14 and line DIN 16, respectively, and the input signal of input line DIP 14 changes from high level to low level, NMOS transistor M1 10 switches from a conductive state to a nonconductive state and NMOS transistor M2 12 switches from a nonconductive state to a conductive state. The path of the constant current switches and a voltage drop occurs at source termination resistor R2 6 without a voltage drop occurring at source termination resistor R1 4. The signal at output node 17 coupled to chip pad DON 20 changes to high level and the signal at output node 19 coupled to chip pad DOP 18 changes to low level.

The CML driver circuit 2 is coupled to components illustrated in FIG. 1 on an external integrated circuit chip or board 36 in order to implement an AC-coupled double termination data transmission link. The components coupled to CML driver circuit 2 include a capacitor C1 22, capacitor C2 24, end termination resistor R3 26, end termination resistor R4 28, termination supply voltage Vterm 30, and amplifier 32. A first terminal of capacitor C1 22 is coupled to DOP 18 and a first terminal of capacitor C2 24 is coupled to DON 20. A first terminal of end termination resistor R3 26 is coupled to the second terminal of capacitor C1 22. The second terminal of end termination resistor R3 26 is coupled to termination supply voltage Vterm 30. A first terminal of end termination resistor R4 28 is coupled to the second terminal of capacitor C2 24. The second terminal of end termination resistor R4 28 is coupled to termination supply voltage Vterm 30.

Capacitor C1 22 and capacitor C2 24 operate to decouple the DC voltages of V_{DD} 8 and Vterm 30. This decoupling allows different voltages at the source and end terminals being applied, which is an important feature for advanced semiconductor technology since the devices manufactured by different process technologies from different vendors can inter-operate easily. Due to the presence of the AC coupling capacitors C1 22 and C2 24, the DC biasing current and AC current flowing through the transistors M1 10 and M2 12 differ. The DC loading resistances and AC loading resistances seen by M1 and M2 at DOP and DON are R1 4 ohms and (R1 4)/2 Ohms respectively.

For better signal quality, it is usually preferred that the CML driver circuit 2 drive a large output swing signal at chip pads DOP 18 and DON 20. For example, large swing signaling provides better signal-to-noise ratio, and is thus preferred in many applications such as PCI Express, Fibre Channel, Serial ATA, DisplayPort, etc.

However, recent trends are to continually decrease chip supply voltages. Decreasing the supply voltage V_{DD} 8 creates a design challenge to maintain driving a large output swing at pads DOP 18 and DON 20. A lower supply voltage V_{DD} 8 results in a lower common mode voltage at DOP 18 and DON 20. Below a certain level, the transistors M1 10 and M2 12 are forced out of good biasing conditions.

For low supply voltage V_{DD} 8 applications, it is difficult if not impossible to bias the transistors M1 10 and M2 12 in the saturation range such that the CML driver circuit 2 can operate smoothly. If transistors M1 10 and M2 12 are not operating in saturation range, a larger transistor is required to switch the large sink current, thereby decreasing operating speed of the circuit. Furthermore, if transistors M1 10 and M2 12 are not operating in saturation range, the turn on resistance of the transistors decreases the CML driver output impedance, thereby decreasing performance of the CML driver.

For example, in a typical application the operating parameters are a supply voltage V_{DD} of 1.2V and the CML driver to output a 1200 mV differential swing. These values are typical application requirements for a 0.13 micron CMOS technology process node. Termination resistors R1 4, R2 6, R3 26, and R4 28 typically have a value of 50 Ohms. To provide a 1200 mV differential output swing, current source Iₛᵢₙₖ 38 has a value of 24 mA to switch the transistors M1 10 and M2 12. Current source Iₛᵢₙₖ 38 may be implemented by a NMOS transistor operating in saturation. The common mode voltage V_{cm} of the CML driver circuit 2 at output node 17 and output node 19 is as follows:

V_{cm}=V_{DD}−R1*Iₛᵢₙₖ/2

In the present example, V_{cm}=600 mV referred to ground. In order to output a 1200 mV differential swing with V_{cm}=600 mV, the single-ended output low voltage is 300 mV and the high voltage is 900 mV respectively on the driver output node 17 and driver output node 19. The above analysis leads to the conclusion that the bias voltage available across the drain and source (Vds) of the NMOS transistors M1 10 and M2 12 plus the voltage across the drain and source of the current sink Iₛᵢₙₖ 38 is only 300 mV when supply voltage V_{DD} 8 is 1.2 V. This total voltage Vds plus the voltage across the drain and source of the current sink Iₛᵢₙₖ 38 is referred to as the voltage “headroom” of the CML driver circuit. It becomes problematic to operate M1 10 and M2 12 in the desired saturation mode and operate current source Iₛᵢₙₖ 38 at the desired current level as headroom voltage decreases. For example, it is problematic to operate M1 10 and M2 12 in the desired saturation mode and operate current source Iₛᵢₙₖ 38 with a value of 24 mA where the bias voltage across the drain and source of the NMOS transistors M1 10 and M2 12 plus the voltage across the drain and source of the current sink Iₛᵢₙₖ 38 is only 300 mV. Furthermore, if the supply voltage V_{DD} 8 is decreased further, there is decreased voltage available to operate M1 10, M2 12, and current source Iₛᵢₙₖ 38.

In the prior art, the supply voltage V_{DD} 8 was chosen to be sufficiently high to properly bias M1 10, M2 12 and Iₛᵢₙₖ 38 in the circuit illustrated in FIG. 1. Alternatively, the supply voltage V_{DD} 8 may be selectively raised as needed. These techniques are discussed in C. T. Chuang, “High-speed low power cross-coupled active-pull-down ECL circuit”, IEEE J. solid-state circuits, VOL. 30, NO. 6, pp. 701-705, June 1995; Jong K. Kim, “High speed current mode logic amplifier using positive feedback and feed-forward source-follower techniques for high speed CMOS IO buffer”, IEEE J. solid-state circuits, VOL. 40, No. 3, pp. 796-802, March 2005; and Lei Luo, John M. Wilson, “3 Gb/s AC coupled chip-to-chip communication using a low swing pulse receiver”, IEEE J. solid-state circuits, VOL. 41, No. 1, January 2006.

However, raising the supply voltage increases the power consumption of the circuit. A higher supply voltage also requires greater reliability of the semiconductor devices, resulting in greater engineering effort and higher costs. Furthermore, for deep submicron semiconductor devices, a higher supply voltage may not always be feasible.

Thus, there is a need for improved systems and methods for high speed current mode logic circuits.

### BRIEF DESCRIPTION OF THE DRAWINGS

The present invention will be readily understood by the following detailed description in conjunction with the accompanying drawings, wherein like reference numerals designate like structural elements.

FIG. 1 illustrates a prior art CML driver in an AC-coupled double termination data transmission link.

FIG. 2 illustrates a circuit for increasing operating headroom of a CML driver in an AC-coupled double termination data transmission link.

FIG. 3 illustrates a circuit for increasing operating headroom of a CML driver in an AC-coupled double termination data transmission link in a further example of the invention.

### DESCRIPTION OF SPECIFIC EMBODIMENTS

Systems and methods for low supply voltage, large output swing, source-terminated output driver for high speed ac-coupled double-termination serial links are disclosed. The following description is presented to enable any person skilled in the art to make and use the invention. Descriptions of specific embodiments and applications are provided only as examples and various modifications will be readily apparent to those skilled in the art. The general principles defined herein may be applied to other embodiments and applications without departing from the spirit and scope of the invention. Thus, the present invention is to be accorded the widest scope encompassing numerous alternatives, modifications and equivalents consistent with the principles and features disclosed herein. For purpose of clarity, details relating to technical material that is known in the technical fields related to the invention have not been described in detail so as not to unnecessarily obscure the present invention.

Particular circuit layouts and circuit components may be given for illustrative purposes. This is done for illustrative purposes to facilitate understanding only and one of ordinary skill in the art may vary the design and implementation parameters and still remain within the scope of the invention.

Generally this description relates to the design and manufacture of integrated semiconductor circuits. In particular, circuits that provide low supply voltage, large output swing, source-terminated output drivers for high speed ac-coupled double-termination serial links are discussed. The systems and methods described herein can be applied to any high speed current mode logic (CML) design to allow decreased supply voltage while maintaining large output swing. Typical applications include, but are not limited to, PCI Express, Fibre Channel, HDMI/DVI, DisplayPort, Serial ATA, SONET, Rapid IO, and XAUI. The systems and methods can be used in AC-coupled double-termination serial links.

In one example, the circuits and methods boost the common mode supply voltage while maintaining the same source termination impedance values. Active components in the form of additional DC current sources are added to a CML driver circuit to boost the common mode voltage. The additional DC current sources drawn from a power supply provides a DC path for the output driver, and a high impedance of the DC current sources maintain the desired output termination resistor values.

In one example of the invention, a current mode logic circuit includes a current mode logic driver circuit and a transistor biasing improvement circuit. The current mode logic driver circuit includes a first transistor and a second transistor in a differential pair configuration. A first source termination resistor is coupled to a first transistor drain at a first output node and a second source termination resistor is coupled to a second transistor drain at a second output node. The transistor biasing improvement circuit is coupled to the current mode logic circuit and includes a first current source coupled to the first output node and a second current source coupled to the second output node. The first current source and the second current source raise a common mode voltage at the first output node and the second output node.

In one example of the invention, a current mode logic circuit includes a first transistor having a first transistor gate, a first transistor source, and a first transistor drain. A second transistor includes a second transistor gate, a second transistor source, and a second transistor drain. A first data input terminal is coupled to the first transistor gate and a second data input terminal is coupled to the second transistor gate. A first source termination resistor having a first terminal is coupled to the first transistor drain and a second terminal coupled to a supply voltage. A second source termination resistor having a third terminal is coupled to the second transistor drain and a fourth terminal coupled to the supply voltage. The circuit further includes a first output node coupled to the first transistor drain and a second output node coupled to the second transistor drain. A first current source is coupled to the first output node and is operable to raise a first common mode voltage at the first output node. A second current source is coupled to the second output node and is operable to raise a second common mode voltage at the second output node.

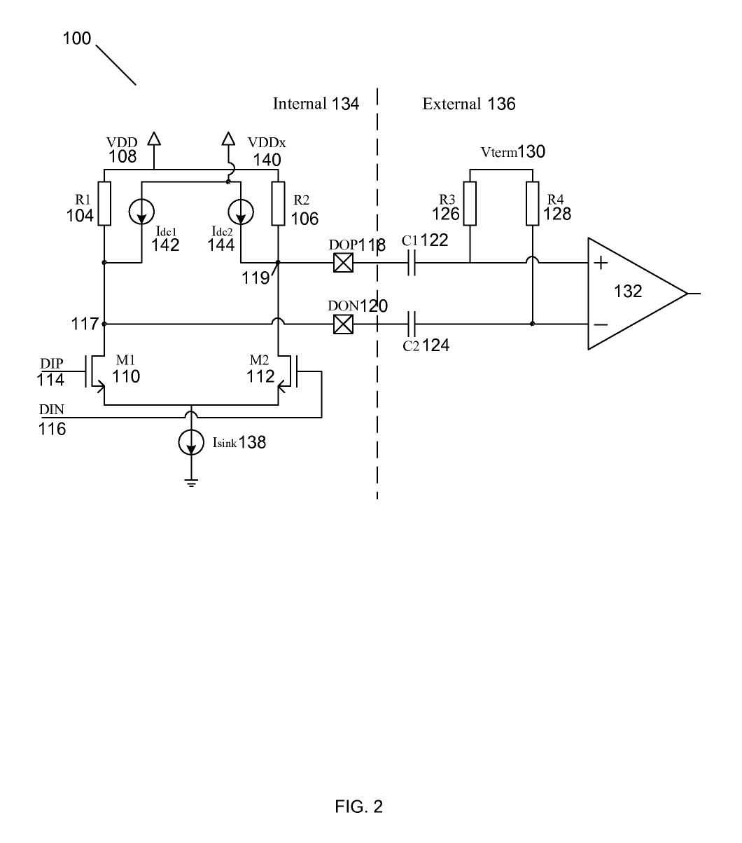

Referring to FIG. 2, a CML driver circuit 100 in one example of the invention is illustrated. The CML driver circuit 100 includes a transistor biasing improvement circuit as described below. A CML driver circuit 100 located internal to an integrated circuit chip 134 consists of a differential pair of transistors NMOS transistor M1 110, NMOS transistor M2 112, source termination resistors R1 104, R2 106, and a current source Iₛᵢₙₖ 138 that feeds the sources of the differential transistor pair. While MOS transistors may be used in the examples herein, other transistor types may be employed as well.

The CML driver circuit 100 utilizes NMOS transistors M1 110 and M2 112 as a differential logic pair. The gate electrode of NMOS transistor M1 110 is connected to an input line DIP 114, the source electrode is connected to constant-current source Iₛᵢₙₖ 138, and the drain electrode is connected to an output node 117 connected to chip pad DON 120 and source termination resistor R1 104. The gate electrode of NMOS transistor M2 112 is connected to input line DIN 116, the source electrode is connected to constant current source Iₛᵢₙₖ 138, and the drain electrode is connected to an output node 119 connected to chip pad DOP 118 and source termination resistor R2 106. A supply voltage V_{DD} 108 is coupled to R1 104 and R2 106.

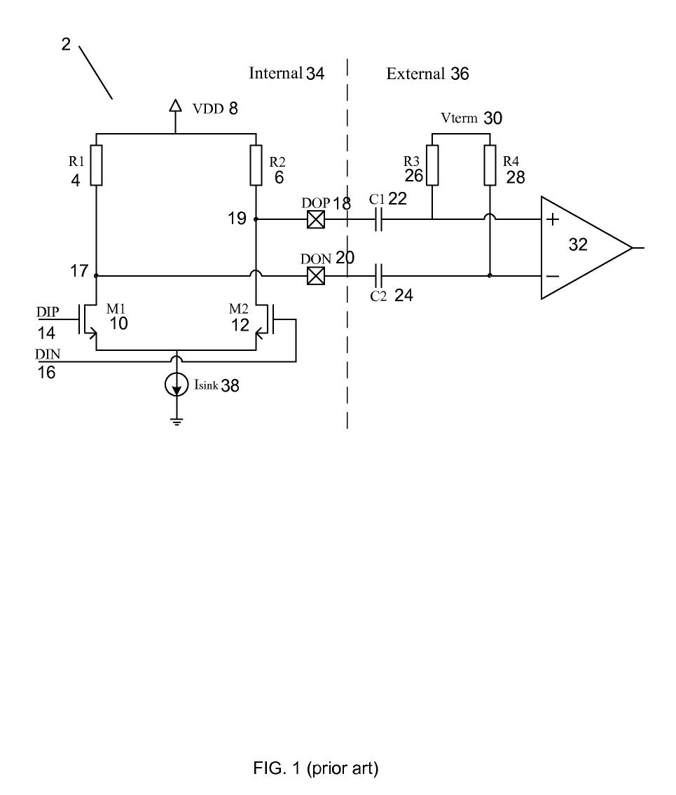

A current source I_{dc1} 142 is coupled to output node 117. A current source I_{dc2} 144 is coupled to output node 119. Current source I_{dc1} 142 and current source I_{dc2} 144 may be driven by a supply voltage VDDx 140. Current source I_{dc1} 142 and current source I_{dc2} operate to improve biasing of NMOS transistor M1 110 and M2 112 for a given values of supply voltage V_{DD} 108, resistor R1 104, and resistor R2 106 by raising the common mode voltage at node 117 and node 119. Current sources I_{dc1} 142 and I_{dc2} 144 act to increase the drain voltages of transistors M1 110 and M2 112 higher than in the prior art CML driver circuit shown in FIG. 1. Source termination resistance values are set by R1 104 and R2 106. The added current sources I_{dc1} 142 and I_{dc2} 144 operate as a transistor biasing improvement circuit coupled to a traditional CML driver circuit to solve the above mentioned headroom issue with the conventional CML driver for low supply voltage and large output swing applications. In one example, current sources I_{dc1} 142 and I_{dc2} 144 are implemented using transistors. For example, such transistors may include without limitation PMOS or PNP Bipolar transistors. Referring to FIG. 4, in one example current source I_{dc1} 142 is shown implemented with a PMOS transistor M4 342, and current source I_{dc2} 144 is shown implemented with a PMOS transistor M5 344. A bias control voltage V_{BP} 352 is coupled to the gate electrode of PMOS transistor M4 342 and the gate electrode of PMOS transistor M5 344. Current source Iₛᵢₙₖ 138 is shown implemented with an NMOS transistor M3 338 with a bias control voltage V_{BN} 350.

The operation of the CML driver circuit 100 will next be explained with reference to FIG. 2. In one example where the CML driver circuit 100 is used in an AC-coupled double termination data transmission link, CML driver circuit 100 is coupled to components illustrated in FIG. 2 on an external integrated circuit chip or board 136. The components coupled to CML driver circuit 100 include a capacitor C1 122, capacitor C2 124, end termination resistor R3 126, end termination resistor R4 128, termination supply voltage Vterm 130, and amplifier 132. A first terminal of capacitor C1 122 is coupled to DOP 118 and a first terminal of capacitor C2 124 is coupled to DON 120. A first terminal of end termination resistor R3 126 is coupled to the second terminal of capacitor C1 122. The second terminal of end termination resistor R3 126 is coupled to termination supply voltage Vterm 130. A first terminal of end termination resistor R4 128 is coupled to the second terminal of capacitor C2 124. The second terminal of end termination resistor R4 128 is coupled to termination supply voltage Vterm 130.

Capacitor C1 122 and capacitor C2 124 operate to decouple the DC voltages of V_{DD} 108 and Vterm 130. This decoupling allows different voltages at the source and end terminals being applied, which is an important feature for advanced semiconductor technology since the devices manufactured by different process technologies from different vendors can inter-operate easily.

In operation, CML driver circuit 100 allows for a low supply voltage, large output swing, source terminated output driver. I_{dc1} 142 and I_{dc2} 144 are sinking currents from VDDx 140 towards M1 110 and M2 112. Since the AC coupling capacitors block the DC current flowing towards the end termination resistors R3 126 and R4 128, all I_{dc1} 142 and I_{dc2} 144 currents are forced into M1 110 and M2 112. In one example, supply voltage V_{DDx} 140 can be equal to supply voltage V_{DD} 108 for a simplified driver power rail design. In a further example, V_{DDx} 140 can be another I/O supply voltage. Typically, V_{DDx} 140 is greater than or equal to V_{DD} 108. In one example, the current sources I_{dc1} 142 and I_{dc2} 144 are also implemented by transistors, requiring a V_{DDx} 140 sufficiently high to allow effective implementation of I_{dc1} 142 and I_{dc2} 144. The current sources I_{dc1} 142 and I_{dc2} 144 should have a very large effective impedance over the operation frequency range of the CML driver to ensure that the desired source termination resistor values are determined solely by R1 104 and R2 106.

The added current sources I_{dc1} 142 and I_{dc2} 144 increase the common mode voltage seen at driver output pads DOP 118 and DON 120, and to keep the output termination resistances un-altered, where the output termination resistance is the output resistance seen into the output pad. By these two current sources I_{dc1} 142 and I_{dc2} 144, the common mode voltage at output node 119 (output pad DOP 118) and output node 117 (output pad DON 120) is raised by I_{dc1}*Rterm, where Rterm is the single-ended source termination resistor (R1 104 or R2 106), and I_{dc1} 142 equals to I_{dc2} 144. Thus, the common mode voltage V_{cm} at output node 117 and output node 119 is as follows:

V_{cm}=V_{DD}−R1*Iₛᵢₙₖ/2+I_{dc1}*Rterm

Compared to the prior art circuit illustrated in FIG. 1, the increased common mode voltage at DOP 118 and DON 120 enlarges the head room voltage of the NMOS transistors M1 110 and M2 112 for a given value of supply voltage V_{DD}, thereby improving biasing of the NMOS transistors M1 110 and M2 112. CML driver circuit 100 achieves a high speed data driving without the need for external biasing or raising the supply voltage. On-chip implementation provides an economic implementation and potential higher speed operation since off-chip parasitics are avoided. The CML driver circuit 100 is particularly useful for advanced technologies with continuously shrinking feature size and decreasing supply voltages. The circuit provides a method for the CML driver to be integrated on a large chip. For many port applications, the on-chip implementation is particularly valuable since the cost savings over on-board implementation are significant.

In one example application, where the supply voltage V_{DD} 108 is equal to 1.2 V, the desired differential output swing is 1200 mV, and the resistors R1 104, R2 106, R3 126, and R4 128 are all 50 Ohms, if the current sources I_{dc1} 142 and I_{dc2} 144 are set to 6 mA, the common mode voltage of the driver is raised to 900 mV. The extra 300 mV voltage is allocated to the switch transistors M1 110 and M2 112, and the current source Iₛᵢₙₖ 138. As such, there will be a 600 mV headroom voltage for NMOS transistors M1 110 and M2 112 and the current source Iₛᵢₙₖ 138. The biasing condition of transistors M1 110 and M2 112 is thus improved by a factor of two this example relative to the prior art circuit of FIG. 1. The implementation of such a biasing condition for the NMOS transistors and NMOS sink current source becomes feasible and efficient.

In a further example, the current sources I_{dc1} 142 and I_{dc2} 144 have a value equal to half the value of the current source Iₛᵢₙₖ 138. In this manner, all DC biasing current of the CML driver is through the current sources I_{dc1} 142 and I_{dc2} 144. V_{DD} 108 is now only used to set the common mode voltage of the CML driver. To extend the concept further, V_{DD} 108 can be floating (no connection) by using a common mode feedback circuit to set the DOP 118 and DON 120 DC voltages. The major benefit from such an implementation is associated with processing technology advancement. High speed and high data throughput are always in demand and technology scaling pushes semiconductor speeds higher. Generally, for reliable operation, transistors with reduced feature sizes have to operate under low voltage. The circuit 100 invention solves the contradictive requirements from manufacturing (lower voltage) and signal quality (large swing). For dual gate oxide CMOS process technology, thick oxide transistors can operate under high supply voltage while thin oxide transistors need low supply voltage. I_{dc1} 142 and I_{dc2} 144 can be implemented by thick oxide transistors, which means V_{DDx} 140 can be much higher than V_{DD} 8.

To achieve a high speed operation, the output driving transistors M1 110 and M2 112 are implemented by thin oxide transistors. The R1 104 and R2 106 tied to V_{DD} 108 together with the I_{dc1} 142 and I_{dc2} 144 set the common mode voltage. The only basic limitation is that the specific technology reliability requires no over-stressing of the M1 110 and M2 112 at the drain side. In other words, I_{dc1} 142 and I_{dc2} 144 operate to overcome the lower supply voltage, and M1 110 and M2 112 are used to achieve high speed operation.

In a further example, I_{dc1} 142 is replaced with a resistor and inductor in series and I_{dc2} 144 is replaced with a resistor and inductor in series. The resistors have a value equal to R1 104 and R2 106 respectively. At the targeted operation frequency, the two inductors have large impedance values which operate to block the AC current into this AC current choking branch. The equivalent termination resistances are held at the desired values set by R1 104 and R2 106.

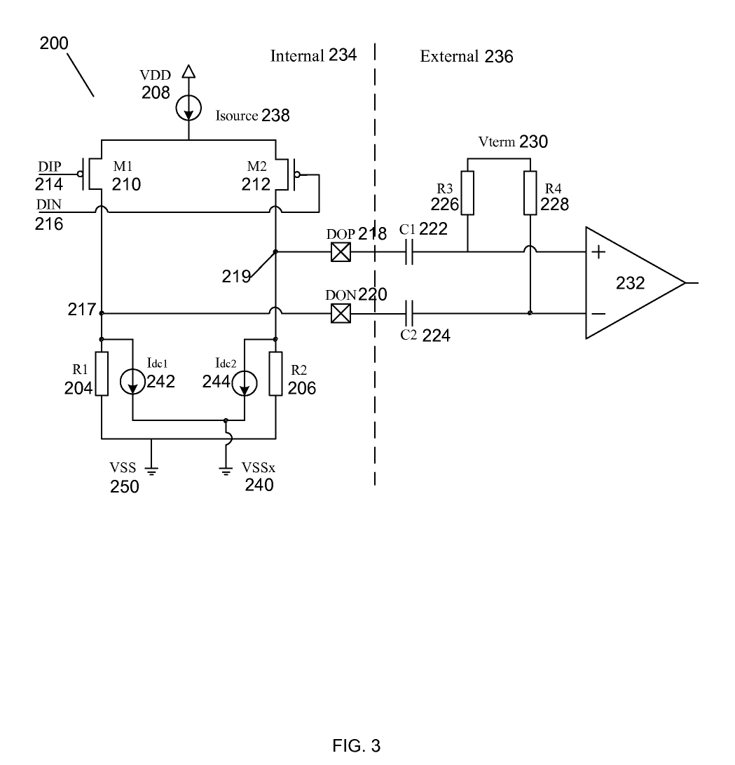

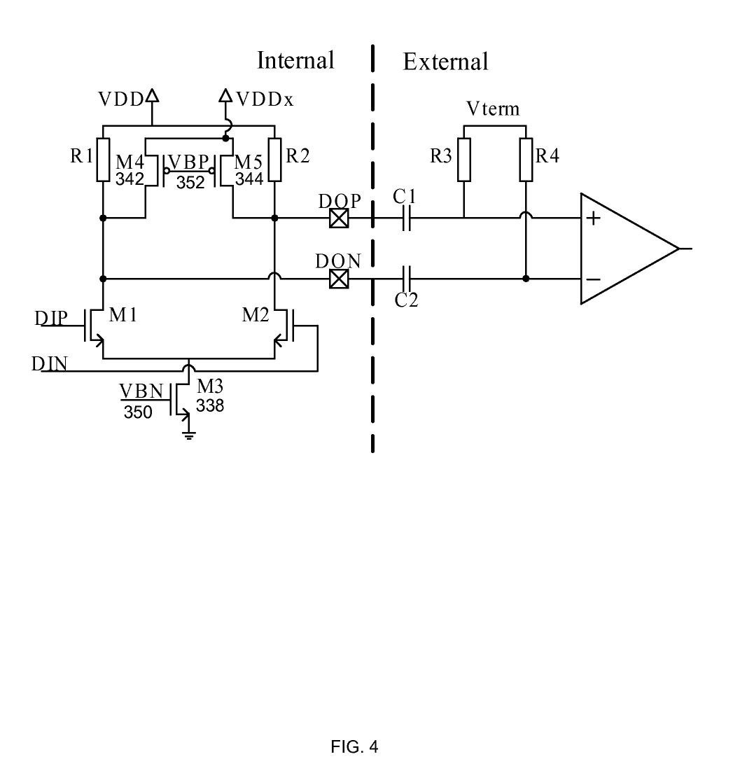

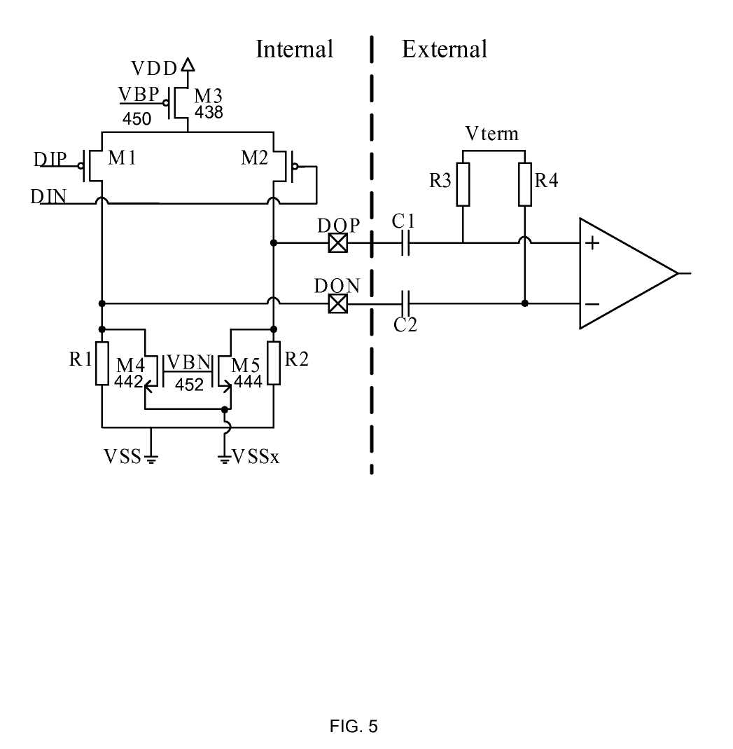

FIG. 2 illustrates a supply referenced CML driver circuit. Referring to FIG. 3, in a further example of the invention a ground referenced CML driver circuit is illustrated. Referring to FIG. 3, a CML driver circuit 200 in one example of the invention is illustrated. The CML driver circuit 200 includes a transistor biasing improvement circuit as described below. A CML driver circuit 200 located internal to an integrated circuit chip 234 consists of a differential pair of transistors PMOS transistor M1 210, PMOS transistor M2 212, source termination resistors R1 204, R2 206, and a current source Isource 238 that feeds the sources of the differential transistor pair.

The CML driver circuit 200 utilizes PMOS transistors M1 210 and M2 212 as a differential logic pair. The gate electrode of PMOS transistor M1 210 is connected to an input line DIP 214, the source electrode is connected to constant-current source Isource 238, and the drain electrode is connected to an output node 217 connected to chip pad DON 220 and source termination resistor R1 204. The gate electrode of PMOS transistor M2 212 is connected to input line DIN 216, the source electrode is connected to constant current source Isource 238, and the drain electrode is connected to an output node 219 connected to chip pad DOP 218 and source termination resistor R2 206. A supply voltage V_{DD} 208 is coupled to current source Isource 238. A supply voltage Vss 250 is coupled to R1 204 and R2 206.

A current source I_{dc1} 242 is coupled to output node 217. A current source I_{dc2} 244 is coupled to output node 219. Current source I_{dc1} 242 and current source I_{dc2} 244 may be driven by a supply voltage Vssx 240. Current source I_{dc1} 242 and current source I_{dc2} operate to improve biasing of PMOS transistor M1 210 and M2 212 for a given values of supply voltage V_{DD} 208, resistor R1 204, and resistor R2 206 by raising the common mode voltage at node 217 and node 219. The added current sources I_{dc1} 242 and I_{dc2} 244 help to increase the transistors M1 210 and M2 212 drain voltages higher than in the conventional structure. Source termination resistance values are set by R1 204 and R2 206. The added current sources I_{dc1} 242 and I_{dc2} 244 operate as a transistor biasing improvement circuit coupled to a traditional CML driver circuit to solve the above mentioned headroom issue with the conventional CML driver for low supply voltage and large output swing applications. In one example, current sources I_{dc1} 242 and I_{dc2} 244 are implemented using transistors. Referring to FIG. 5, current source I_{dc1} 242 is shown implemented with a NMOS transistor M4 442, and current source I_{dc2} 244 is shown implemented with a NMOS transistor M5 444. A bias control voltage V_{BN} 452 is coupled to the gate electrode of NMOS transistor M4 442 and the gate electrode of NMOS transistor M5 444. Current source Iₛᵢₙₖ 238 is shown implemented with a PMOS transistor M3 438 having a bias control voltage V_{BP} 450.

In one example where the CML driver circuit 200 is used in an AC-coupled double termination data transmission link, CML driver circuit 200 is coupled to components illustrated in FIG. 3 on an external integrated circuit chip or board 236. The components coupled to CML driver circuit 200 include a capacitor C1 222, capacitor C2 224, end termination resistor R3 226, end termination resistor R4 228, termination supply voltage Vterm 230, and amplifier 232. A first terminal of capacitor C1 222 is coupled to DOP 218 and a first terminal of capacitor C2 224 is coupled to DON 220. A first terminal of end termination resistor R3 226 is coupled to the second terminal of capacitor C1 222. The second terminal of end termination resistor R3 226 is coupled to termination supply voltage Vterm 230. A first terminal of end termination resistor R4 228 is coupled to the second terminal of capacitor C2 224. The second terminal of end termination resistor R4 228 is coupled to termination supply voltage Vterm 230. In operation, the ground referenced CML driver circuit 200 operates in a manner similar to the CML driver circuit 100 as described above in reference to FIG. 2.

Although example circuit configurations have been described in certain example of the invention, one of ordinary skill in the art will recognize that except as otherwise described herein other configurations and components may be used to perform similar functions. While the exemplary embodiments of the present invention are described and illustrated herein, it will be appreciated that they are merely illustrative and that modifications can be made to these embodiments without departing from the spirit and scope of the invention. Thus, the scope of the invention is intended to be defined only in terms of the following claims as may be amended, with each claim being expressly incorporated into this Description of Specific Embodiments as an embodiment of the invention.

What is claimed is:

1. A current mode logic circuit comprising:
a current mode logic driver circuit comprising a first transistor and a second transistor in a differential pair configuration, wherein a first source termination resistor is coupled to a first transistor drain at a first output node and a second source termination resistor is coupled to a second transistor drain at a second output node;
a transistor biasing improvement circuit coupled to the current mode logic circuit, comprising:
a first current source coupled to the first output node; and
a second current source coupled to the second output node, wherein the first current source and the second current source raise a common mode voltage at the first output node and the second output node.

2. The current mode logic circuit of claim 1, wherein the current mode logic driver circuit and transistor biasing improvement circuit are disposed on a single integrated circuit.

3. The current mode logic circuit of claim 1, wherein a supply voltage is coupled to the first source termination resistor and the second source termination resistor.

4. The current mode logic circuit of claim 1, wherein a supply voltage is coupled to the first current source and the second current source.

5. The current mode logic circuit of claim 1, wherein the first current source comprises a third transistor and the second current source comprises a fourth transistor.

6. The current mode logic circuit of claim 1, wherein a first supply voltage is coupled to the first source termination resistor and the second source termination resistor and a second supply voltage is coupled to the first current source and the second current source.

7. The current mode logic circuit of claim 6, wherein the first supply voltage is equal to the second supply voltage.

8. The current mode logic circuit of claim 6, wherein the second supply voltage is greater than or equal to the first supply voltage.

9. The current mode logic circuit of claim 1, wherein the first current source and the second current source have a large effective impedance.

10. The current mode logic circuit of claim 1, wherein the common mode voltage at the first output node and the second output node is raised by an amount equal to a first current source value multiplied by a first source termination resistor value.

11. The current mode logic circuit of claim 1, wherein the first transistor comprises a first thin oxide transistor and the second transistor comprises a second thin oxide transistor.

12. The current mode logic circuit of claim 1, wherein the first transistor comprises a first MOS transistor and the second transistor comprises a second MOS transistor.

13. The current mode logic circuit of claim 1, further comprising a third current source coupled to a first transistor source and a second transistor source, wherein the first current source is equal to half of the third current source and the second current source is equal to half of the third current source.

14. A current mode logic circuit comprising:
a first transistor having a first transistor gate, a first transistor source, and a first transistor drain;
a second transistor having a second transistor gate, a second transistor source, and a second transistor drain;
a first data input terminal coupled to the first transistor gate;
a second data input terminal coupled to the second transistor gate;
a first source termination resistor having a first terminal coupled to the first transistor drain and a second terminal coupled to a supply voltage;
a second source termination resistor having a third terminal coupled to the second transistor drain and a fourth terminal coupled to the supply voltage;
a first output node coupled to the first transistor drain;
a second output node coupled to the second transistor drain;
a first current source coupled to the first output node, wherein the first current source is operable to raise a first common mode voltage at the first output node; and
a second current source coupled to the second output node, wherein the second current source is operable to raise a second common mode voltage at the second output node.

15. The current mode logic circuit of claim 14 wherein the first current source comprises a third transistor and the second current source comprises a fourth transistor.

16. The current mode logic circuit of claim 14, wherein the first current source and the second current source have a large effective impedance.

17. The current mode logic circuit of claim 14, wherein the common mode voltage at the first output node and the second output node is raised by an amount equal to a first current source value multiplied by a first source termination resistor value.

18. The current mode logic circuit of claim 14, wherein the first transistor comprises a first thin oxide transistor and the second transistor comprises a second thin oxide transistor.

19. The current mode logic circuit of claim 14, wherein the first transistor comprises a first MOS transistor and the second transistor comprises a second MOS transistor.

20. The current mode logic circuit of claim 14, further comprising a third current source coupled to the first transistor source and the second transistor source, wherein the first current source is equal to half of the third current source and the second current source is equal to half of the third current source.

21. The current mode logic circuit of claim 14, wherein a current source supply voltage is coupled to the first current source and the second current source.

22. The current mode logic circuit of claim 21, wherein the supply voltage is equal to the current source supply voltage.

23. The current mode logic circuit of claim 21, wherein the current source supply voltage is greater than or equal to the supply voltage.

24. A current mode logic circuit comprising:
a current mode logic driver circuit comprising a first transistor and a second transistor in a differential pair configuration, wherein a first source termination resistor is coupled to a first transistor drain at a first output node and a second source termination resistor is coupled to a second transistor drain at a second output node;
a circuit coupled to the current mode logic circuit, comprising:
a first current source means coupled to the first output node for raising a common mode voltage at the first output node; and
a second current source means coupled to the second output node for raising the common mode voltage at the second output node.

25. The current mode logic circuit of claim 24, wherein the common mode voltage at the first output node and the second output node is raised by an amount equal to a first current source value multiplied by a first source termination resistor value.

26. The current mode logic circuit of claim 24, wherein the first transistor comprises a first thin oxide transistor and the second transistor comprises a second thin oxide transistor.

27. The current mode logic circuit of claim 24, wherein the first transistor comprises a first MOS transistor and the second transistor comprises a second MOS transistor.
